(19) United States
(12) Patent Application Publication
(10) Pub. No.: US 2008/0290528 A1
(43) Pub. Date: Nov. 27, 2008

(54) SEMICONDUCTOR PACKAGE SUBSTRATE HAVING ELECTRICAL CONNECTING PADS

(75) Inventor: Shih-Ping HSU, Hsin-chu (TW)

Correspondence Address: SAWYER LAW GROUP LLP, 2465 E. Bayshore Road, Suite No. 406, PALO ALTO, CA, 94303, US

(73) Assignee: PHOENIX PRECISION TECHNOLOGY CORPORATION, Hsin-chu (TW)

(21) Appl. No.: 11/838,665

(22) Filed: Aug. 14, 2007

(30) Foreign Application Priority Data
May 22, 2007 (TW) 096208206

(51) Int. Cl. H01L 23/48

(52) U.S. Cl. 257/779

(57) ABSTRACT

A semiconductor package substrate having electrical connecting pads includes: a substrate body having a plurality of electrical connecting pads formed on surface thereof, and a plurality of protruding lumps or concave areas of any geometric shape respectively formed on surfaces of the electrical connecting pads for increasing contact surfaces of the electrical connecting pads, thereby preventing detaching of conductive elements from surfaces of the electrical connecting pads caused by poor bonding force.

### BACKGROUND OF THE INVENTION

1. Field of the Invention

The present invention relates generally to a semiconductor package substrate having electrical connecting pads, and more particularly to a semiconductor package substrate having electrical connecting pads with protruding lumps or concave areas of any geometric shape on surface thereof.

2. Description of Related Art

Along with rapid development of electronic industries, electronic product research has focused on multi-function and high performance. To meet requirements of semiconductor packages for high integration and miniaturization, double layer circuit boards have been replaced by multi-layer circuit boards and interlayer connection techniques have been used to increase available circuit layout areas in a limited space.

According to flip chip techniques, a plurality of electrode pads is formed on active surface of a semiconductor chip and a plurality of electrical connecting pads is formed on a semiconductor package substrate corresponding to the electrode pads, and conductive elements or other conductive adhesive material is formed between the electrode pads of the semiconductor chip and the electrical connecting pads of the semiconductor package substrate for providing both electrical connection and mechanical connection between the semiconductor chip and the semiconductor package substrate.

FIG. 1 is a diagram showing a conventional flip-chip structure. As shown in FIG. 1, a substrate body 11 is provided, which comprise a first surface 11a of chip side and a second surface 11b of ball side. A plurality of first electrical connecting pads 111 is formed on the first surface 11a for electrically connecting with a semiconductor chip 12, and a plurality of first conductive elements 13a made of solder material is formed on surfaces of the first electrical connecting pads 111. Further, a plurality of second electrical connecting pads 112 is formed on the second surface 11b for electrically connecting with other electronic devices such as a printed circuit board, and a plurality of second conductive elements 13b made of solder material is formed on surfaces of the second electrical connecting pads 112. The semiconductor chip 12 has a plurality of electrode pads 121. Metallic bumps 14 are formed on surfaces of the electrode pads 121 and flip-chip mounted to the first conductive elements 13a of the substrate body 11. Then at a reflow temperature capable of melting the first conductive elements 13a, the first conductive elements 13a are reflowed to the corresponding metallic bumps 14, thereby electrically connecting the semiconductor chip 12 with the substrate body 11.

As shown in FIG. 2A, the first surface 11a and the second surface 11b of a substrate body 11 are respectively covered by a first insulating protection layer 15a and a second insulating protection layer 15b, and the first and second insulating protection layers 15a, 15b respectively have a plurality of openings 150a, 150b for exposing part of surfaces of the first and second electrical connecting pads 111, 112. Accordingly the first and second electrical connecting pads 111, 112 are SMD (Solder Mask Defined) pads, that is, the insulating protection layer partially covers periphery of the pads. As shown in FIG. 2B, surfaces of the first and second electrical connecting pads 111, 112 are completely exposed from the openings 150a′, 150b′ of the first and second insulating protection layers 15a′, 15b′, and the first and second electrical connecting pads 111, 112 are accordingly NSMD (Non Solder Mask Defined) pads, that is, periphery of the pads are not covered by the insulating protection layer. First conductive elements 13a are formed on surfaces of the first electrical connecting pads 111 in the openings 150a, 150a′ of the first insulating protection layers 15a, 15a′ and second conductive elements 13b are formed on surfaces of the second electrical connecting pads 112 in the openings 150b, 150b′ of the second insulating protection layers 15b, 15b′.

However, corresponding to fine pitch requirement of the semiconductor chip 12, pitch between the first electrical connecting pads 111 is decreased, and area of the first electrical connecting pads 111 is also gradually decreased. As a result, contact area between the first conductive elements 13a and the corresponding first electrical connecting pads 111 is gradually decreased, which reduces the bonding force between the first conductive elements 13a and the first electrical connecting pads 111, and accordingly the first conductive elements 13a are easy to detach from the first electrical connecting pads 111. Meanwhile, decreasing of the openings 150a, 150a′ of the first insulating protection layer 15a in size corresponding to the first electrical connecting pads 111 also reduces the contact area between the first conductive elements 13a and the first electrical connecting pads 111. Same problem also occurs to the second electrical connecting pads 112.

For example, pitch between the second electrical connecting pads 112 is decreased from 800 μm to 400 μm, and the diameter of the openings for the second electrical connecting pads 112 is decreased from 500 μm to 250 μm. Thus, the contact area is decreased to be quarter of the initial contact area, which seriously reduces the bonding force.

Therefore, how to provide a structure capable of increasing the bonding force between electrical connecting pads and conductive elements so as to avoid detaching of conductive elements from electrical connecting pads due to decreased bonding area has become urgent.

### SUMMARY OF THE INVENTION

According to the above drawbacks, an objective of the present invention is to provide a semiconductor package substrate having electrical connecting pads, wherein a plurality of protruding lumps or concave areas of any geometric shape is formed on surfaces of the electrical connecting pads for increasing contact area of the electrical connecting pads.

Another objective of the present invention is to provide a semiconductor package substrate having electrical connecting pads, wherein a plurality of protruding lumps or concave areas of any geometric shape is formed on surfaces of the electrical connecting pads for increasing bonding force of the electrical connecting pads with conductive elements.

In order to attain the above and other objectives, the present invention discloses a semiconductor package substrate, which comprises: a substrate body; a plurality of electrical connecting pads formed on surface of the substrate body; and a plurality of protruding lumps respectively formed on surfaces of the electrical connecting pads for increasing contact area of the electrical connecting pads.

According to another embodiment of the present invention, the semiconductor package substrate having electrical connecting pads comprises: a substrate body; a plurality of electrical connecting pads formed on surface of the substrate body; and a plurality of concave areas respectively formed on surfaces of the electrical connecting pads for increasing contact area of the electrical connecting pads.

The longitudinal section of the concave areas has a form of narrow top and wide bottom for increasing the bonding of the electrical connecting pads. A surface layer is formed on surfaces of the protruding lumps or concave areas. The surface layer can be made of one of the group consisting of Pb, Sn, Ag, Cu, Au, Bi, Sb, Zn, Ni, Pd, Mg, In, Te and Ga. Alternatively, the surface layer can comprise layers of at least two kinds of metals or is an alloy layer made of at least two metals, wherein the metals are selected from the group consisting of Pb, Sn, Ag, Cu, Au, Bi, Sb, Zn, Ni, Pd, Mg, In, Te and Ga; or the surface layer can be made of an OSP layer.

An insulating protection layer can be formed on surface of the substrate body and have a plurality of openings for exposing surfaces of the electrical connecting pads such that conductive elements can be formed on the exposed surfaces of the electrical connecting pads and other electronic device such as semiconductor chip can further be electrically connected with the semiconductor package substrate through the conductive elements. The electrical connecting pads can be SMD pads or NSMD pads.

Therefore, according to the present invention, a plurality of protruding lumps or concave areas of any geometric shape is formed on surfaces of the electrical connecting pads such that the electrical connecting pads can obtain larger contact area, thereby increasing the bonding area of conductive elements on surfaces of the electrical connecting pads and preventing detaching of the conductive elements from the electrical connecting pads.

### BRIEF DESCRIPTION OF DRAWINGS

FIG. 1 is a diagram of a conventional semiconductor package substrate with a semiconductor chip disposed on surface thereof;

FIG. 2A is a diagram of a conventional semiconductor package substrate with SMD pads formed on surface thereof;

FIG. 2B is a diagram of a conventional semiconductor package substrate with NSMD pads formed on surface thereof;

FIGS. 3A to 3D are sectional diagrams showing a semiconductor package substrate having electrical connecting pads according to a first embodiment of the present invention;

FIG. 3C′ is an upper view of the semiconductor package substrate of FIG. 3C;

FIG. 3C″ is a diagram showing an alternative structure of the semiconductor package substrate of FIG. 3C;

FIG. 3D′ is a diagram showing an alternative structure of the semiconductor package substrate of FIG. 3D;

FIG. 3D″ is a diagram showing an alternative structure of the semiconductor package substrate of FIG. 3D;

FIGS. 4A to 4D are sectional diagrams showing a semiconductor package substrate having electrical connecting pads according to a second embodiment of the present invention;

FIG. 4B′ is a sectional diagram showing an alternative structure of concave areas of FIG. 4B;

FIG. 4C′ is an upper view of the semiconductor package substrate of FIG. 4C;

FIG. 4C″ is a diagram showing an alternative structure of the semiconductor package substrate of FIG. 4C; and

FIG. 4D′ is a diagram showing an alternative structure of the semiconductor package substrate of FIG. 4D.

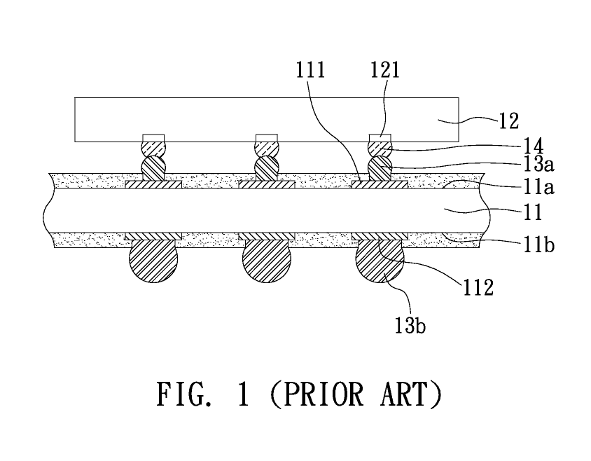

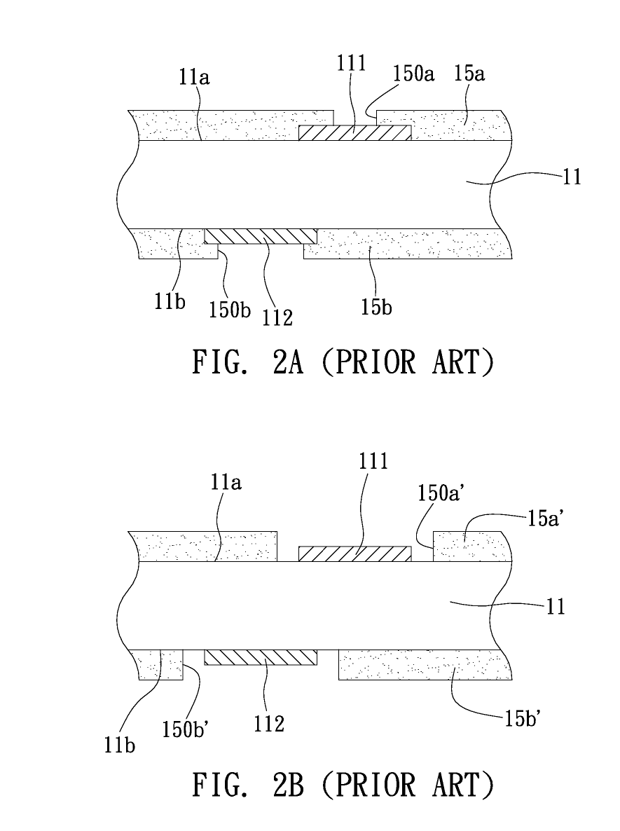

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

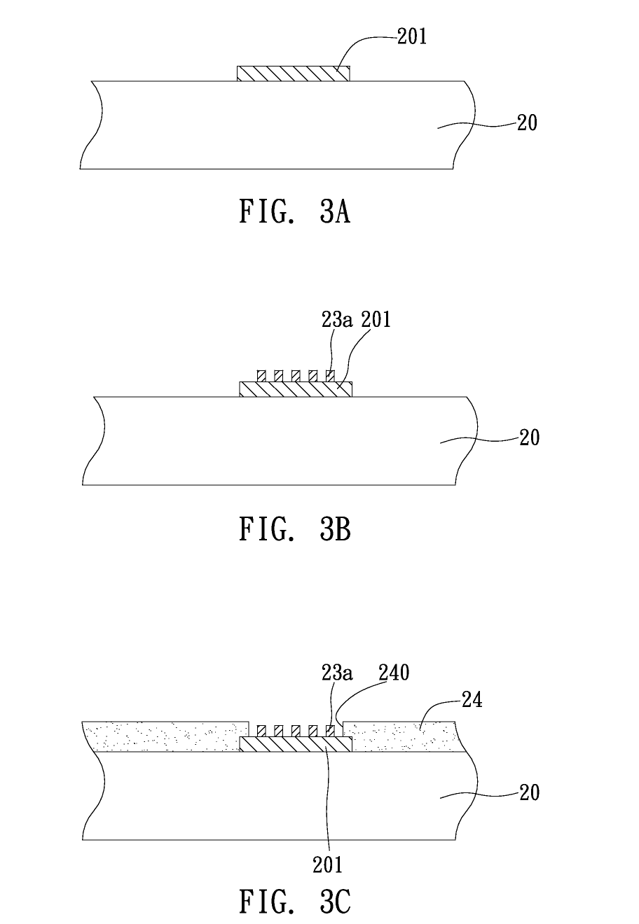

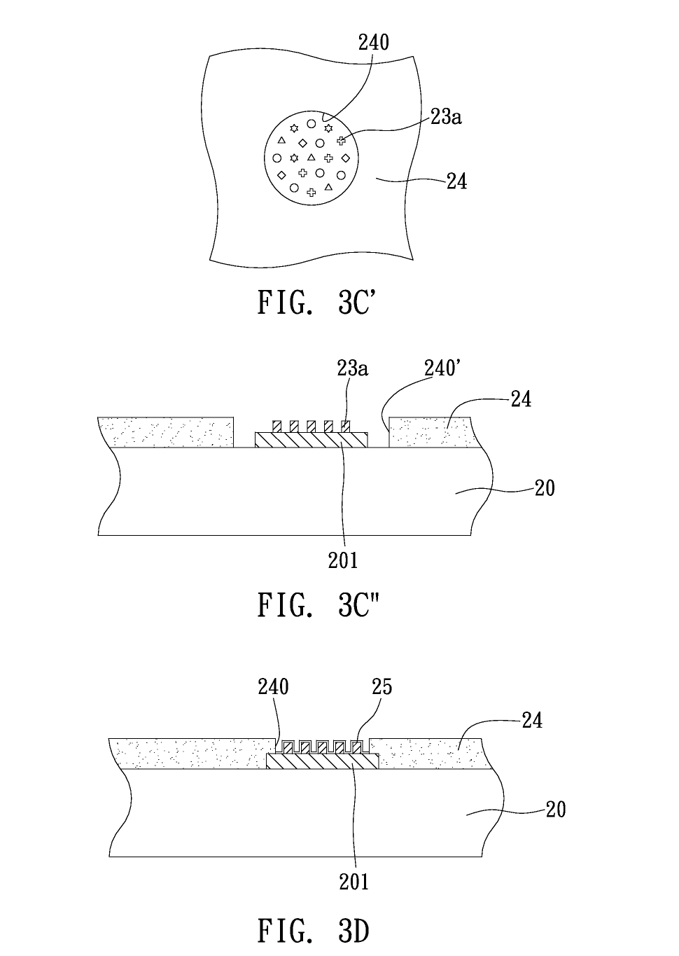

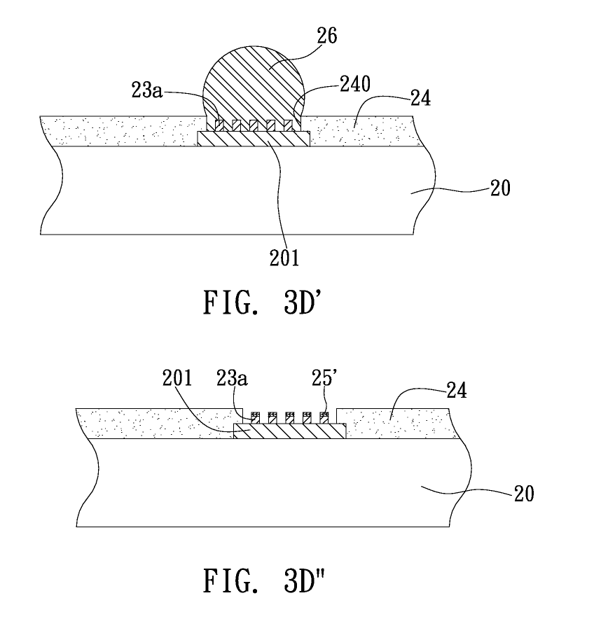

FIGS. 3A to 3D are sectional diagrams showing a fabrication method of a semiconductor package substrate having electrical connecting pads according to a first embodiment of the present invention.

As shown in FIG. 3A, a substrate body 20 having an electrical connecting pad 201 is provided. It should be noted that although the present embodiment exemplifies one electrical connecting pad 201 for clarifying characteristics of the present invention, the present invention is not limited to the present embodiment. Those skilled in the art will understand that there is generally a plurality of electrical connecting pads on surface of the substrate body of chip side and even of ball side.

As shown in FIG. 3B, protruding lumps 23a of any geometric shape such as round shape, elliptic shape, rectangle shape, irregular shape or any combination thereof are formed on surface of the electrical connecting pad 201 by electroplating so as to increase contact area of the electrical connecting pad 201.

As shown in FIG. 3C, an insulating protection layer 24 is formed on surface of the substrate body 20 and an opening 240 is formed in the insulating protection layer 24 for exposing part of surface of the electrical connecting pad 201. As a result, the electrical connecting pad 201 is a SMD (Solder Mask Defined) pad. The protruding lumps 23a can be of any geometric shape, as shown in FIG. 3C′ which is an upper view of the structure in FIG. 3C. Alternatively, as shown in FIG. 3C″, the whole surface of the electrical connecting pad 201 is exposed from the opening 240′ formed in the insulating protection layer 24, and as a result, the electrical connecting pad 201 is a NSMD (Non Solder Mask Defined) pad.

As shown in FIG. 3D, a surface layer 25 of an OSP layer can further be formed on surfaces of the electrical connecting pad 201 and the protruding lumps 23a for preventing oxidation of the electrical connecting pad 201 and the protruding lumps 23a.

Alternatively, as shown in FIG. 3D′, a conductive element 26 such as solder material is formed in the opening 240 of the insulating protection layer 24 such that other electronic devices such as a semiconductor chip or a printed circuit board can be electrically connected with the semiconductor package substrate through the conductive element 26.

As shown in FIG. 3D″, a surface layer 25′ made of metal material is formed on upper surfaces of the protruding lumps 23a, wherein the surface layer 25′ can be a layer made of one of the group consisting of Pb, Sn, Ag, Cu, Au, Bi, Sb, Zn, Ni, Pd, Mg, In, Te, and Ga. Alternatively, the surface layer can comprise layers made of at least two kinds of metals or is an alloy layer made of at least two metals, wherein the metals are selected from the group consisting of Pb, Sn, Ag, Cu, Au, Bi, Sb, Zn, Ni, Pd, Mg, In, Te and Ga.

Therefore, the semiconductor package substrate having electrical connecting pads of the present invention comprises: a substrate body 20; a plurality of electrical connecting pads 201 formed on surface of the substrate body 20; and a plurality of protruding lumps 23a formed on surfaces of the electrical connecting pads 201 for increasing contact area of the electrical connecting pads 201.

An insulating protection layer 24 is formed on surface of the substrate body 20, and a plurality of openings 240 is formed in the insulating protection layer 24 for exposing part of surfaces of the electrical connecting pads 201. The electrical connecting pads 201 are SMD pads. Alternatively, surfaces of the electrical connecting pads 201 can be completely exposed from the openings 240′ of the insulating protection layer 24, and the electrical connecting pads 201 are NSMD pads.

A surface layer 25 of an OSP layer is formed on surfaces of the protruding lumps 23a.

Alternatively, conductive elements 26 are formed on surfaces of the electrical connecting pads 201 in the openings 240, 240′ such that other electronic devices such as a semiconductor chip or a printed circuit board can be electrically connected with the semiconductor package substrate through the conductive elements 26.

Alternatively, a surface layer 25′ made of metal material can be formed on upper surfaces of the protruding lumps 23a.

### Second Embodiment

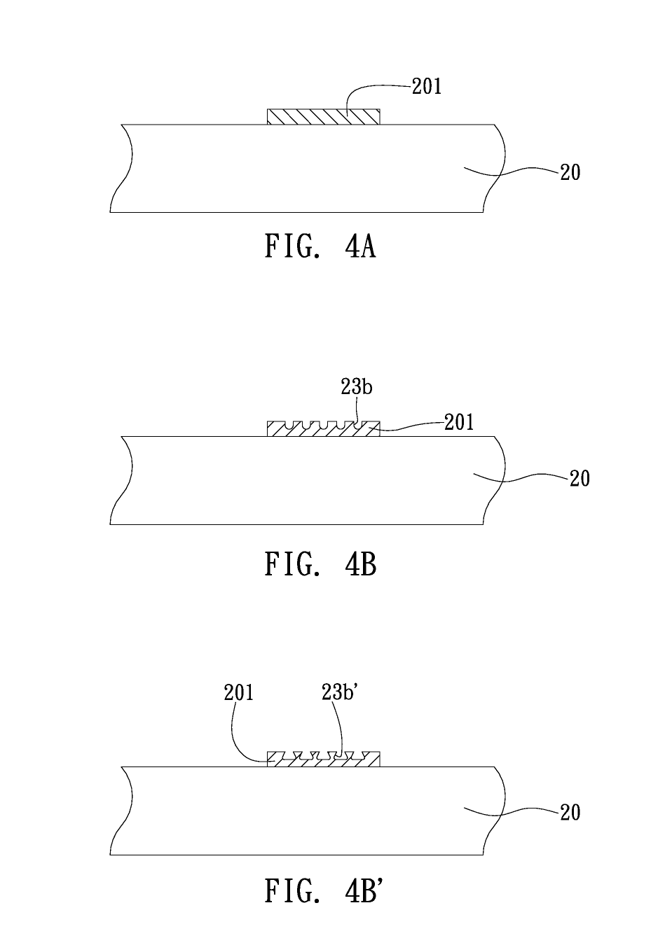

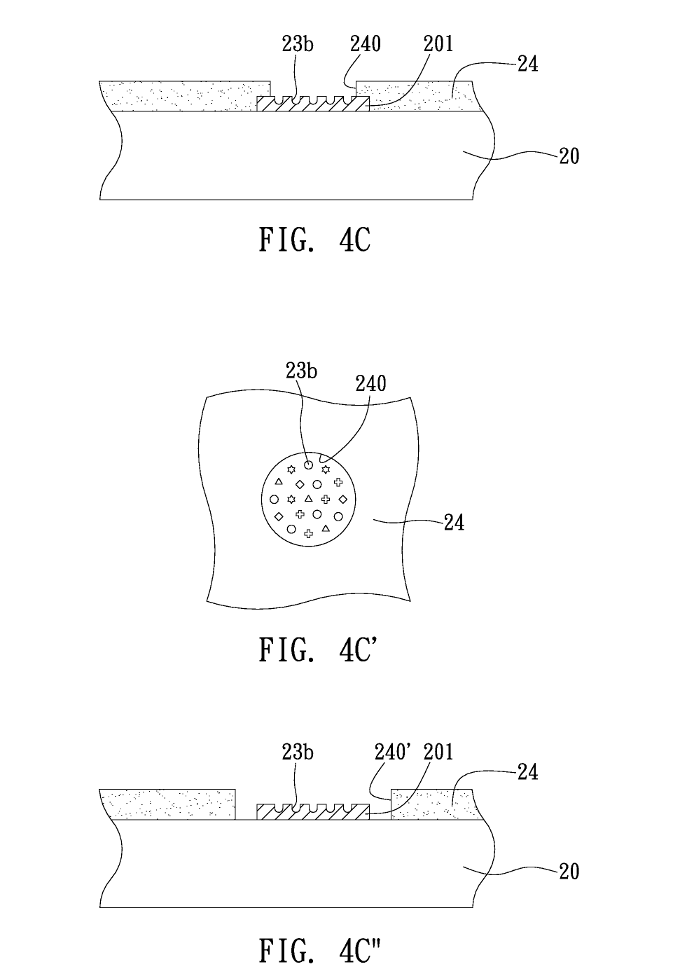

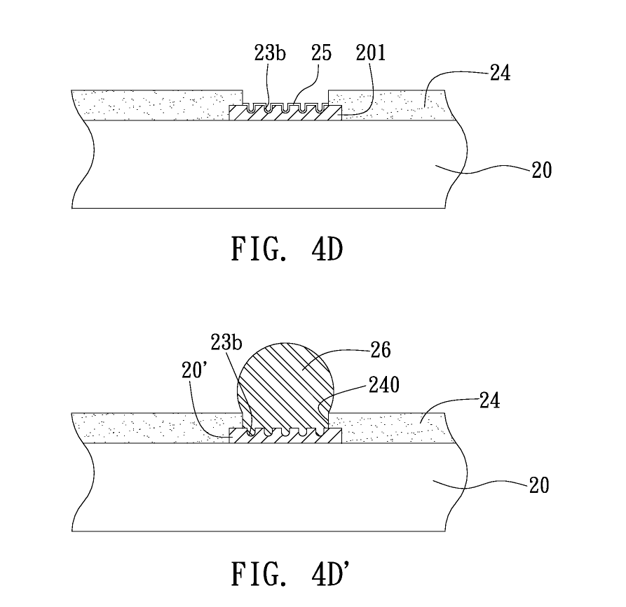

FIGS. 4A to 4D are sectional diagrams showing a fabrication method of a semiconductor package substrate having electrical connecting pads according to a second embodiment of the present invention. The difference of the present embodiment from the first embodiment is that a plurality of concave areas is formed on surfaces of the electrical connecting pads by etching.

As shown in FIG. 4A, a substrate body 20 having a plurality of electrical connecting pads 201 formed on surface thereof is provided.

As shown in FIGS. 4B and 4B′, concave areas 23b are formed on surfaces of the electrical connecting pads 201 by etching, horizontal section of the concave areas 23b can be of any geometric shape such as round shape, elliptic shape, rectangular shape, irregular shape or any combination thereof, as shown in FIG. 4B; or by prolonging the etching time, longitudinal section of the concave grooves 23b′ formed on surfaces of the electrical connecting pads 201 has narrow top and wide bottom, thereby increasing the bonding of the surfaces of the electrical connecting pads 201, as shown in FIG. 4B′.

As shown in FIG. 4C, an insulating protection layer 24 is formed on surface of the substrate body 20 and openings 240 are formed in the insulating protection layer 24 for exposing part of surfaces of the electrical connecting pads 201, and the electrical connecting pads 201 are SMD pads. As shown in FIG. 4C′ which is an upper view of the semiconductor package substrate of FIG. 4C, the concave areas 23b can be of any geometric shape. Or as shown in FIG. 4C″, openings 240′ are formed in the insulating protection layer 24 for completely exposing surfaces of the electrical connecting pads 201, and the electrical connecting pads 201 are NSMD pads.

As shown in FIG. 4D, a surface layer 25 is formed on surfaces of the electrical connecting pad 201 and the concave areas 23b.

Alternatively, as shown in FIG. 4D′, conductive elements 26 are formed in the openings 240 of the insulating protection layer 24 such that other electronic devices such as a semiconductor chip or a printed circuit board can be electrically connected with the semiconductor package substrate through the conductive elements 26.

Therefore, the semiconductor package substrate having electrical connecting pads of the present invention comprises: a substrate body 20; a plurality of electrical connecting pads 201 formed on surface of the substrate body 20; and a plurality of concave areas 23b formed on surfaces of the electrical connecting pads 201 for increasing contact area of the electrical connecting pads 201.

An insulating protection layer 24 is formed on surface of the substrate body 20, and a plurality of openings 240 is formed in the insulating protection layer 24 for exposing part of surfaces of the electrical connecting pads 201, and accordingly the electrical connecting pads 201 are SMD pads. Alternatively, surfaces of the electrical connecting pads 201 can be completely exposed from the openings 240′ of the insulating protection layer 24, and the electrical connecting pads 201 are NSMD pads.

A surface layer 25 of an OSP layer or metal material is formed on surfaces of the concave areas 23b.

Alternatively, conductive elements 26 are formed on surfaces of the electrical connecting pads 201 in the openings 240, 240′ such that other electronic devices such as a semiconductor chip can be electrically connected with the semiconductor package substrate through the conductive elements 26.

As shown in FIG. 4B′, the longitudinal section of the concave areas 23b′ has a form of narrow top and wide bottom so as to further increase bonding of surfaces of the electrical connecting pads.

Therefore, according to the semiconductor package substrate having electrical connecting pads of the present invention, a plurality of protruding lumps or concave areas of any geometric shape is formed on surfaces of the electrical connecting pads so as to increase the contact area of the electrical connecting pads, thereby increasing the bonding area of conductive elements on surfaces of the electrical connecting pads and preventing detaching of the conductive elements from the electrical connecting pads.

The above-described descriptions of the detailed embodiments are only to illustrate the preferred implementation according to the present invention, and it is not to limit the scope of the present invention, accordingly, all modifications and variations completed by those with ordinary skill in the art should fall within the scope of present invention defined by the appended claims.

What is claimed is:

1. A semiconductor package substrate having electrical connecting pads, comprising:
a substrate body;
a plurality of electrical connecting pads formed on surface of the substrate body; and
a plurality of protruding lumps respectively formed on surfaces of the electrical connecting pads for increasing contact area of the electrical connecting pads.

2. The semiconductor package substrate of claim 1, wherein horizontal section of the protruding lumps is of any geometric shape.

3. The semiconductor package substrate of claim 1 further comprising a surface layer formed on the protruding lumps.

4. The semiconductor package substrate of claim 3, wherein the surface layer is made of one of the group consisting of Pb, Sn, Ag, Cu, Au, Bi, Sb, Zn, Ni, Pd, Mg, In, Te and Ga.

5. The semiconductor package substrate of claim 3, wherein the surface layer comprises layers of at least two kinds of metals or is an alloy layer made of at least two metals, wherein the metals are selected from the group consisting of Pb, Sn, Ag, Cu, Au, Bi, Sb, Zn, Ni, Pd, Mg, In, Te and Ga.

6. The semiconductor package substrate of claim 3, wherein the surface layer is an OSP layer.

7. The semiconductor package substrate of claim 1 further comprising an insulating protection layer formed on surface of the substrate body and having openings for exposing the electrical connecting pads.

8. The semiconductor package substrate of claim 7, further comprising conductive elements formed on surfaces of the electrical connecting pads in the openings of the insulating protection layer.

9. The semiconductor package substrate of claim 7, wherein each electrical connecting pad is one of a SMD (Solder Mask Defined) pad and a NSMD (Non Solder Mask Defined) pad.

10. A semiconductor package substrate having electrical connecting pads, comprising:
a substrate body;
a plurality of electrical connecting pads formed on surface of the substrate body; and
a plurality of concave areas respectively formed on surfaces of the electrical connecting pads for increasing contact area of the electrical connecting pads.

11. The semiconductor package substrate of claim 10, wherein horizontal section of the concave areas is of any geometric shape.

12. The semiconductor package substrate of claim 10, wherein longitudinal sectional of the concave areas has a form of narrow top and wide bottom.

13. The semiconductor package substrate of claim 10, further comprising a surface layer formed on the concave areas.

14. The semiconductor package substrate of claim 13, wherein the surface layer is one of the group consisting of Pb, Sn, Ag, Cu, Au, Bi, Sb, Zn, Ni, Pd, Mg, In, Te and Ga.

15. The semiconductor package substrate of claim 13, wherein the surface layer comprises layers of at least two kinds of metals or is an alloy layer made of at least two metals, wherein the metals are selected from the group consisting of Pb, Sn, Ag, Cu, Au, Bi, Sb, Zn, Ni, Pd, Mg, In, Te and Ga.

16. The semiconductor package substrate of claim 13, wherein the surface layer is an OSP layer.

17. The semiconductor package substrate of claim 10, further comprising an insulating protection layer formed on surface of the substrate body and having openings for exposing the electrical connecting pads.

18. The semiconductor package substrate of claim 17, further comprising conductive elements formed on surfaces of the electrical connecting pads in the openings of the insulating protection layer.

19. The semiconductor package substrate of claim 17, wherein each electrical connecting pad is one of a SMD (Solder Mask Defined) pad and a NSMD (Non Solder Mask Defined) pad.
